(19) United States
(12) Patent Application Publication
(10) Pub. No.: US 2020/0127215 A1
(43) Pub. Date: Apr. 23, 2020

(54) OLED DISPLAY SUBSTRATE AND METHOD FOR PREPARING THE SAME, AND DISPLAY DEVICE

(71) Applicant: BOE Technology Group Co., Ltd., Beijing (CN)

(72) Inventors: Hejin WANG, Beijing (CN); Pinfan WANG, Beijing (CN)

(21) Appl. No.: 16/410,434

(22) Filed: May 13, 2019

(30) Foreign Application Priority Data
Oct. 18, 2018 (CN) 201811214552.7

(51) Int. Cl. H01L 51/00; H01L 51/52; H01L 51/56; H01L 27/32

(52) U.S. Cl. CPC H01L 51/0096; H01L 51/5271; H01L 2251/566; H01L 27/3246; H01L 2251/53; H01L 51/56

(57) ABSTRACT

An embodiment of the present disclosure provides a method for preparing the OLED display substrate, including: forming an inverted frustum structure surrounding an cutting region of the OLED display substrate, such that when forming a cathode of the OLED display substrate, the cathode fractures spontaneously at an edge of an upper surface of the inverted frustum structure; and a reflective pattern between the inverted frustum structure and a base substrate of the OLED display substrate before forming the inverted frustum structure, such that an orthogonal projection of the inverted frustum structure on the base substrate is located within an orthogonal projection of the reflective pattern on the base substrate.

### CROSS-REFERENCE TO RELATED APPLICATION

This application claims a priority to Chinese Patent Application No. 201811214552.7 filed on Oct. 18, 2018, the disclosures of which are incorporated in their entirety by reference herein.

### TECHNICAL FIELD

The present disclosure relates to the field of display technology, in particular to an OLED display substrate, a method for preparing the same, and a display device.

### BACKGROUND

With the development of flexible display technology, flexible displays of different shapes have satisfied a new requirement, which often need to cut an organic light-emitting display (OLED display) to remove a part of the organic light-emitting display. After the organic light-emitting display panel is cut, the edge of the cutting region is liable to cause water and oxygen to permeate between the layers, thereby causing poor display. In particular, in the case where the cathode of the organic light-emitting display panel is formed on the entire surface by vapor deposition, after the organic light-emitting display panel is cut, water and oxygen are liable to penetrate into the organic light-emitting display screen along the cathode since the side surface of the cathode is exposed.

In order to solve the above problems, in the related art, in the production of the organic light-emitting display panel, an undercut step is provided at the periphery of the cutting region, such that when the cathode is subsequently prepared the cathode will be broken at an edge of an upper surface of the undercut step during the deposition. Then, when the package structure is prepared, the packaging structure is capable of covering an side surface of the cathode, to block water and oxygen from penetrating into the organic light-emitting display along the cathode.

However, the undercut step in the related art is generally formed before the pixel defining layer is formed. When the pixel defining layer is formed after the undercut step is formed, the pixel defining layer material will be filled into the bottom of the undercut step. Since the upper surface of the undercut step blocks the exposure light, it is difficult to remove the pixel defining layer material at the bottom of the undercut step by exposure. Thus, in the subsequent deposition of the cathode, the cathode cannot be broken at the edge of the upper surface of the undercut step, thereby affecting the actual packaging effect and the performance of the organic light-emitting display.

### SUMMARY

An embodiment of the present disclosure provides a technical solution as follows.

In one aspect, a method for preparing an OLED display substrate is provided, including: forming an inverted frustum structure surrounding an cutting region of the OLED display substrate, with an area of an end surface of the inverted frustum structure away from a base substrate of the OLED display substrate being greater than an area of an end surface proximate to the base substrate, such that when forming a cathode of the OLED display substrate, the cathode is broken spontaneously at an edge of an upper surface of the inverted frustum structure.

The method further includes: forming a reflective pattern between the inverted frustum structure and a base substrate of the OLED display substrate before forming the inverted frustum structure, such that an orthogonal projection of the inverted frustum structure on the base substrate is located within an orthogonal projection of the reflective pattern on the base substrate.

Further, the forming the reflective pattern includes: forming the reflective pattern and a first metal layer pattern of the OLED display substrate by a single patterning process.

Further, the forming the inverted frustum structure includes: forming a first pattern and a second pattern which are stacked, with the first pattern being located between the second pattern and the base substrate, and with an orthogonal projection of the first pattern on the base substrate being located within an orthogonal projection of the second pattern on the base substrate.

Further, the forming the first pattern includes: forming a transition pattern of the first pattern; and etching a side surface of the transition pattern of the first pattern with the second pattern as a mask after forming the second pattern, such that the transition pattern of the first pattern is indented inward to form the first pattern.

Further, the forming the transition pattern of the first pattern includes: forming the transition pattern of the first pattern and a second metal layer pattern of the OLED display substrate by a single patterning process.

An embodiment of the present disclosure further provides an OLED display substrate, including: a base substrate; an inverted frustum structure surrounding an cutting region, with an area of an end surface of the inverted frustum structure away from a base substrate of the OLED display substrate being greater than an area of an end surface proximate to the base substrate; a cathode broken spontaneously at an edge of an upper surface of the inverted frustum structure; and a reflective pattern located between the inverted frustum structure and the base substrate, where an orthogonal projection of the inverted frustum structure on the base substrate is located within an orthogonal projection of the reflective pattern on the base substrate.

Further, the OLED display substrate further includes a first metal layer pattern located in a same layer as the reflective pattern and formed of a same material as the reflective pattern.

Further, the inverted frustum structure includes a first pattern and a second pattern, with the first pattern being located between the second pattern and the base substrate, and with an orthogonal projection of the first pattern on the base substrate being located within an orthogonal projection of the second pattern on the base substrate.

Further, the OLED display substrate further includes a second metal layer pattern located in a same layer as the first pattern and formed of a same material as the first pattern.

An embodiment of the present disclosure further provides a display device including the OLED display substrate as described above.

### BRIEF DESCRIPTION OF THE DRAWINGS

FIGS. 1 to 11 are schematic diagrams showing a method for preparing an OLED display substrate according to one embodiment of the present disclosure.

### REFERENCE SIGN

1 base substrate; 2 active layer; 3 first gate insulating layer; 41 gate electrode; 42 reflective pattern; 5 second gate insulating layer; 61 first pattern; 62 second pattern; 63 transition pattern of first pattern; 7 interlayer insulating layer; 81 source electrode; 82 drain electrode; 9 overcoat; 10 anode; 11 pixel definition layer; 12 organic light-emitting layer; 13 cathode; 14 packaging layer; A cutting region.

### DETAILED DESCRIPTION

In order to make the technical problems to be solved, the technical solutions, and the advantages of the examples of the present disclosure, the present disclosure will be described hereinafter in conjunction with the drawings and specific examples.

The embodiments of the present disclosure provide an OLED display substrate, a method for preparing the same and a display device, which are capable of ensuring the packaging effect of the OLED display substrate, thereby ensuring the performance of the display device.

One embodiment of the present disclosure provides a method for manufacturing the OLED display substrate, including: forming an inverted frustum structure surrounding an cutting region of the OLED display substrate, with an area of an end surface of the inverted frustum structure away from a base substrate of the OLED display substrate being greater than an area of an end surface proximate to the base substrate, such that when forming a cathode of the OLED display substrate, the cathode is broken spontaneously at an edge of an upper surface of the inverted frustum structure; and a reflective pattern between the inverted frustum structure and the base substrate before forming the inverted frustum structure, such that an orthogonal projection of the inverted frustum structure on the base substrate is located within an orthogonal projection of the reflective pattern on the base substrate.

In this embodiment, a reflective pattern is formed between the inverted frustum structure and the base substrate. In the preparation of the pixel defining layer, the pixel defining layer material is filled into the bottom of the inverted frustum structure. During the exposure of the pixel defining layer material, the exposure light is reflected by the reflective pattern, the exposure of the pixel-defining layer material at the bottom of the inverted frustum structure is enhanced, and the pixel-defining layer material at the bottom of the inverted frustum structure is completely exposed and removed, thereby preventing the pixel-defining layer material from remaining at the bottom of the inverted frustum structure, and being capable of retaining the original inverted frustum structure. Thus, in the subsequent preparation of the cathode, the cathode will be broken at the edge of the upper surface of the inverted frustum structure during the deposition. In the preparation of the packaging layer, the packaging layer is capable of covering a side surface of the cathode, to block water and oxygen from penetrating into the OLED display substrate along the cathode and to ensure and to ensure the packaging effect of the OLED display substrate, thereby ensuring the performance of the display device, and being capable of preparing a profiled organic light-emitting display.

The reflective pattern can be formed by a special patterning process, or formed simultaneously with other film patterns of the OLED display substrate by a single patterning process. Thus, there is no need for an additional patterning process to form the reflective pattern, thereby reducing the number of the patterning processes for the OLED display substrate, reducing the cost of the OLED display substrate and increasing the productivity of the OLED display substrate.

In one specific embodiment, the forming the reflective pattern includes:

forming the reflective pattern and a first metal layer pattern of the OLED display substrate by a single patterning process. The first metal layer pattern includes a gate and a gate line of a thin-film transistor, and the like.

The inverted frustum structure may be a round inverted frustum structure, or may be composed of a multilayered film layer pattern, in which the area of the film layer pattern is gradually increased along from a direction proximate to the base substrate to a distance away from the base substrate.

In one specific embodiment, the forming the inverted frustum structure includes: forming a first pattern and a second pattern which are stacked, with the first pattern being located between the second pattern and the base substrate, and with an orthogonal projection of the first pattern on the base substrate being located within an orthogonal projection of the second pattern on the base substrate.

Further, the forming the first pattern includes: forming a transition pattern of the first pattern; and etching a side surface of the transition pattern of the first pattern with the second pattern as a mask after forming the second pattern, such that the transition pattern of the first pattern is indented inward to form the first pattern.

Optionally, the material used in the first pattern and the anode of the OLED display substrate use a same etchant. When the anode of the OLED display substrate is etched, the etchant used for the anode of the OLED display substrate can etch the side surface of the transition pattern of the first pattern, such that the transition pattern of the first pattern is indented inward to form the first pattern, and there is no additional etching process for etching the transition pattern of the first pattern.

The transition pattern of the first pattern can be formed by a special patterning process, or formed simultaneously with other film patterns of the OLED display substrate by a single patterning process. Thus, there is no need for an additional patterning process to form the transition pattern of the first pattern, thereby reducing the number of the patterning processes for the OLED display substrate, reducing the cost of the OLED display substrate and increasing the productivity of the OLED display substrate.

In one specific embodiment, the forming the transition pattern of the first pattern includes: forming the transition pattern of the first pattern and the second metal layer pattern of the OLED display substrate by a single patterning process, in which the second metal layer pattern includes a plate of a storage capacitor.

Specifically, the first metal layer pattern may be a first gate metal layer pattern, and the second metal layer pattern may be a second gate metal layer pattern; or the first metal layer pattern may be a second gate metal layer pattern, and the second metal layer pattern can be a source/drain metal layer pattern. When the second metal layer pattern is a source/drain metal layer pattern, the second pattern may be form by the passivation layer on the source/drain metal layer.

An embodiment of the present disclosure further provides an OLED display substrate, including: a base substrate; an inverted frustum structure surrounding an cutting region, with an area of an end surface of the inverted frustum structure away from a base substrate of the OLED display substrate being greater than an area of an end surface proximate to the base substrate; a cathode broken spontaneously at an edge of an upper surface of the inverted frustum structure; and a reflective pattern located between the inverted frustum structure and the base substrate, where an orthogonal projection of the inverted frustum structure on the base substrate is located within an orthogonal projection of the reflective pattern on the base substrate.

In this embodiment, a reflective pattern is formed between the inverted frustum structure and the base substrate. In the preparation of the pixel defining layer, the pixel defining layer material is filled into the bottom of the inverted frustum structure. During the exposure of the pixel defining layer material, the exposure light is reflected by the reflective pattern, the exposure of the pixel-defining layer material at the bottom of the inverted frustum structure is enhanced, and the pixel-defining layer material at the bottom of the inverted frustum structure is completely exposed and removed, thereby preventing the pixel-defining layer material from remaining at the bottom of the inverted frustum structure, and being capable of retaining the original inverted frustum structure. Thus, in the subsequent preparation of the cathode, the cathode will be broken at the edge of the upper surface of the inverted frustum structure during the deposition. In the preparation of the packaging layer, the packaging layer is capable of covering a side surface of the cathode, to block water and oxygen from penetrating into the OLED display substrate along the cathode and to ensure and to ensure the packaging effect of the OLED display substrate, thereby ensuring the performance of the display device, and being capable of preparing a profiled organic light-emitting display.

The reflective pattern can be formed by a special patterning process, or located in a same layer and made of a same materials as other film layers of the OLED display substrate, so that the reflective pattern can be formed simultaneously with other film patterns of the OLED display substrate by a single patterning process. Thus, there is no need for an additional patterning process to form the reflective pattern, thereby reducing the number of the patterning processes for the OLED display substrate, reducing the cost of the OLED display substrate and increasing the productivity of the OLED display substrate.

In one specific embodiment, the reflective pattern and the first metal layer pattern of the OLED display substrate are located in a same layer and formed of a same material. The first metal layer pattern includes a gate and a gate line of a thin-film transistor, and the like.

The inverted frustum structure may be a round inverted frustum structure, or may be an undercut step structure composed of a multilayered film layer pattern, in which the area of the film layer pattern is gradually increased along from a direction proximate to the base substrate to a distance away from the base substrate.

In one specific embodiment, the inverted frustum structure includes: forming a first pattern and a second pattern, with the first pattern being located between the second pattern and the base substrate, and with an orthogonal projection of the first pattern on the base substrate being located within an orthogonal projection of the second pattern on the base substrate.

The transition pattern of the first pattern can be formed by a special patterning process, or located in a same layer and made of a same materials as other film layers of the OLED display substrate, so that the transition pattern of the first pattern can be formed simultaneously with other film patterns of the OLED display substrate by a single patterning process. Thus, there is no need for an additional patterning process to form the transition pattern of the first pattern, thereby reducing the number of the patterning processes for the OLED display substrate, reducing the cost of the OLED display substrate and increasing the productivity of the OLED display substrate.

In one specific embodiment, the first pattern and the second metal layer pattern of the OLED display substrate are located in a same layer and formed of a same material, in which the second metal layer pattern includes a plate of a storage capacitor.

The OLED display substrate and the method for preparing the same of the embodiments of the present disclosure will be further described below in conjunction with the accompanying drawings and specific Examples.

### Example 1

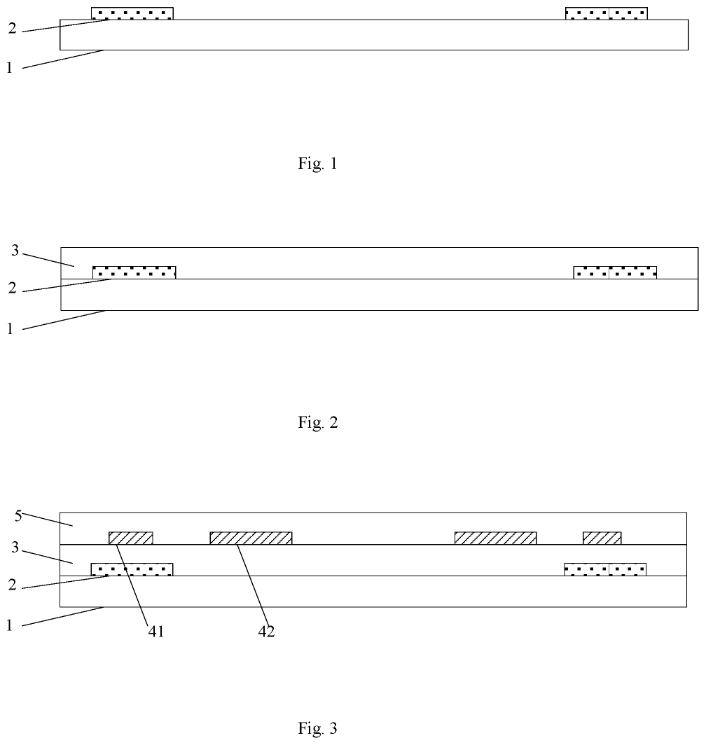

As shown in FIGS. 1 to 11, the method for preparing the OLED display substrate of the present Example includes the following operations (1) to (11).

(1) as shown in FIG. 1, providing a substrate 1, on which an active layer 2 of a thin-film transistor is formed.

The base substrate 1 may be a rigid substrate or a flexible substrate, in which the rigid substrate includes a glass substrate and a quartz substrate, and the flexible substrate includes a PI (polyimide) substrate.

Specifically, a semiconductor material is deposited on the base substrate 1, a layer of photoresist is coated on the semiconductor material, and the photoresist is exposed by using a mask to form a photoresist unreserved region and a photoresist reserved region, in which the photoresist reserved region corresponds to a region in which the pattern of the active layer 2 is located, and the photoresist unreserved region corresponds to a region outside of the pattern of the active layer 2; development processing is performed, so that the photoresist in the photoresist unreserved region is completely removed, and the thickness of the photoresist in the photoresist reserved region remains unchanged; and the semiconductor material of the photoresist unreserved region is completely etched by an etching process to form a pattern of the active layer 2, and the remaining photoresist is stripped.

(2) as shown in FIG. 2, forming a first gate insulating layer 3.

Specifically, a first gate insulating layer 3 having a thickness of 500 to 5,000 Å may be deposited on base substrate of the above (1) by a plasma enhanced chemical vapor deposition (PECVD) method. The first gate insulating layer 3 may be selected from an oxide, a nitride. or an oxynitride, and the reaction gas is SiH₄, NH₃, N₂ or SiH₂Cl₂, NH₃, N₂.

(3) as shown in FIG. 3, forming a thin-film transistor gate 41 and a reflective pattern 42, and then forming a second gate insulating layer 5.

Specifically, a gate metal layer having a thickness of about 500 to 4,000 Å may be deposited on the first gate insulating layer 3 by sputtering or thermal evaporation. The material of the gate metal layer may be selected from Cu, Al, Ag, Mo, Cr, Nd, Ni, Mn, Ti, Ta, W and other metals and alloys of these metals, and the gate metal layer may be a single layer structure or a multilayer structure, such as Cu\Mo, Ti\Al\Ti, and Mo\Al\Mo. A layer of photoresist is coated on the gate metal layer, and the photoresist is exposed by using a mask to form a photoresist unreserved region and a photoresist reserved region, in which the photoresist reserved region corresponds to a region in which the gate electrode 41, the reflective pattern 42 and other first gate metal layer pattern are located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the gate metal film of the photoresist unreserved region is completely etched by an etching process, and the remaining photoresist is stripped to form a gate electrode 41, a reflective pattern 42 and other first gate metal layer pattern.

A second gate insulating layer 5 having a thickness of 500 to 5,000 Å may be deposited by a plasma enhanced chemical vapor deposition (PECVD) method. The second gate insulating layer 5 may be selected from an oxide, a nitride. or an oxynitride, and the reaction gas is SiH₄, NH₃, N₂ or SiH₂Cl₂, NH₃, N₂.

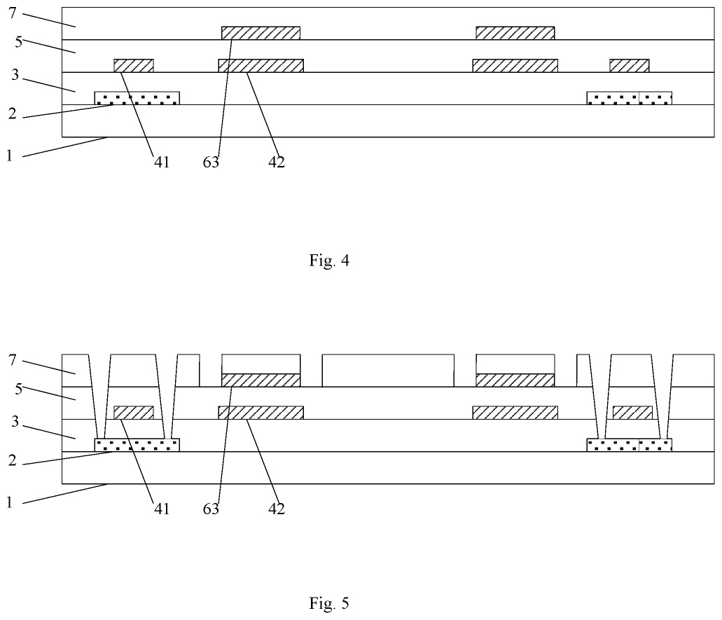

(4) as shown in FIG. 4, forming a transition pattern 63 of the first pattern and an interlayer insulating layer 7.

Specifically, a gate metal layer having a thickness of about 500 to 4,000 Å may be deposited on the second gate insulating layer 5 by sputtering or thermal evaporation. The material of the gate metal layer may be selected from Cu, Al, Ag, Mo, Cr, Nd, Ni, Mn, Ti, Ta, W and other metals and alloys of these metals, and the gate metal layer may be a single layer structure or a multilayer structure, such as Cu\Mo, Ti\Al\Ti, and Mo\Al\Mo. A layer of photoresist is coated on the gate metal layer, and the photoresist is exposed by using a mask to form a photoresist unreserved region and a photoresist reserved region, in which the photoresist reserved region corresponds to a region in which the transition pattern 63 of the first pattern and the second gate metal layer pattern are located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the gate metal film of the photoresist unreserved region is completely etched by an etching process, and the remaining photoresist is stripped to form a transition pattern 63 of the first pattern and a second gate metal layer pattern, in which the transition pattern 63 of the first pattern surrounds the cutting region of the OLED display substrate.

An interlayer insulating layer 7 having a thickness of 500 to 5,000 Å may be deposited by a plasma enhanced chemical vapor deposition (PECVD) method. The interlayer insulating layer 7 may be selected from an oxide, a nitride. or an oxynitride, and the corresponding reaction gas is SiH₄, NH₃, N₂ or SiH₂Cl₂, NH₃, N₂.

(5) as shown in FIG. 5, etching the first gate insulating layer 3, the second gate insulating layer 5 and the interlayer insulating layer 7 to form a via hole exposing the active layer 2 and a via hole exposing a side surface of the transition pattern 63 of the first pattern.

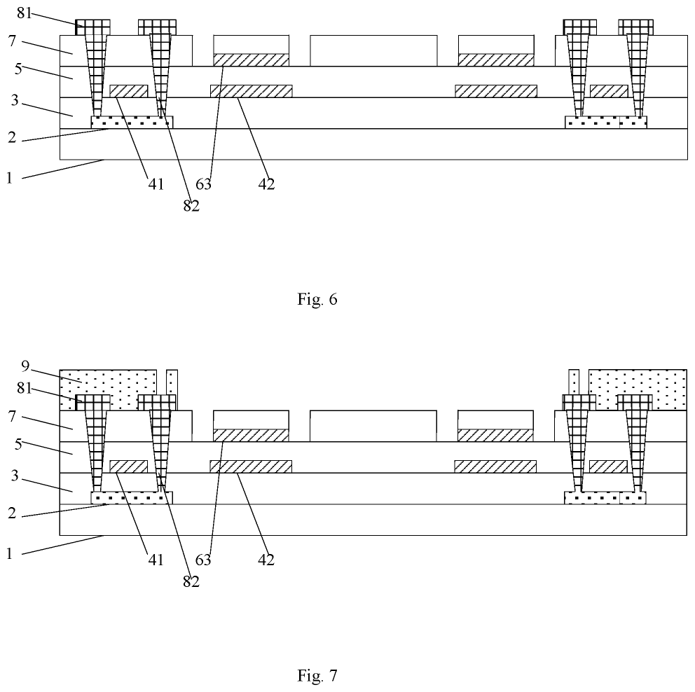

(6) as shown in FIG. 6, forming a source electrode 81 and a drain electrode 82 of the thin-film transistor.

Specifically, by magnetron sputtering, thermal evaporation or other film formation methods, a source/drain metal layer having a thickness of approximately 2000 to 4000 Å may be deposited on the base substrate of the above (5). The material of the source/drain metal layer may be selected from a metal such as Cu, Al, Ag, Mo, Cr, Nd, Ni, Mn, Ti, Ta, and W, and an alloy of these metals. The source/drain metal layer may be a single layer structure or a multilayer structure, such as Cu\Mo, Ti\Al\Ti, and Mo\Al\Mo. One layer of photoresist is coated on the source/drain metal layer, and the photoresist is exposed by using a mask to form a photoresist unreserved region and a photoresist reserved region, in which the photoresist reserved region corresponds to a region in which the patterns of the source electrode 81 and the drain electrode 82 are located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the source/drain metal layer of the photoresist unreserved region is completely etched by an etching process, and the remaining photoresist is stripped to form a source electrode 81 and a drain electrode 82, in which the source electrode 81 and the drain electrode 82 are respectively connected to the active layer 2 through via holes.

(7) as shown in FIG. 7, forming an overcoat 9.

Specifically, a pattern of the overcoat 9 can be formed by coating and exposing one layer of an organic resin on the base substrate 1 of the above (6).

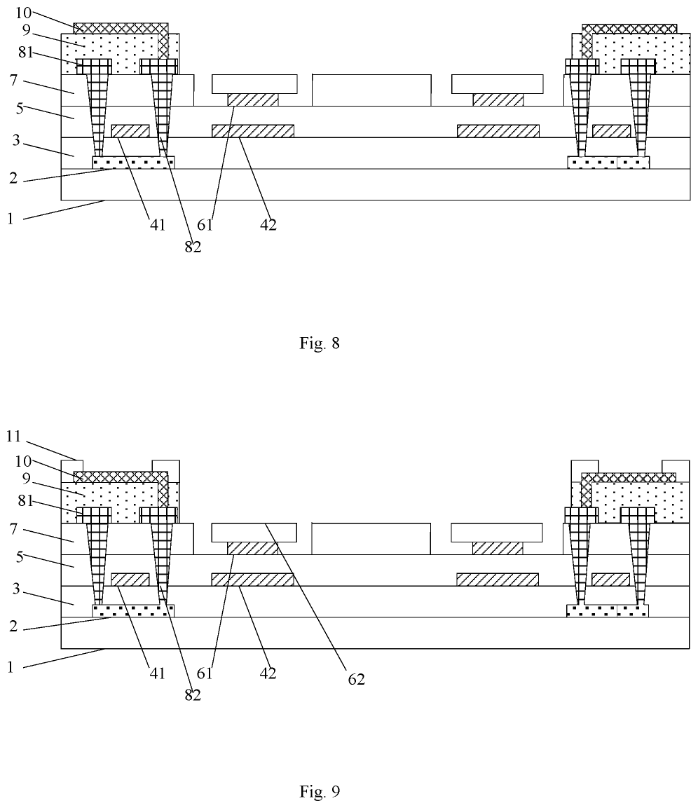

(8) as shown in FIG. 8, forming an anode 10.

Specifically, ITO, Ag and ITO may be deposited in sequence on the base substrate 1 of the above (7), a photoresist is coated on the uppermost ITO, and the photoresist is exposed by using a mask to form a photoresist unreserved region and a photoresist reserved region, in which the photoresist reserved region corresponds to a region in which the pattern of the anode electrode 10 is located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the ITO of the photoresist unreserved region, Ag and ITO are completely etched by an etching process, and the remaining photoresist is stripped to form a pattern of the anode 10.

When ITO, Ag and ITO are etched, the etchant simultaneously etches the exposed side surface of the transition pattern 63 of the first pattern, and the transition pattern 63 is indented inward by 0.1 mm to 10 mm to form the first pattern 61. The first pattern 61 and the remaining interlayer insulating layer portion thereon (i.e., the second pattern 62 shown in FIG. 9) constitute an undercut step structure, in which the undercut step structure surrounds the cutting region of the OLED display substrate, and the orthogonal projection of the first pattern 61 on the base substrate 1 falls within the orthogonal projection of the reflective pattern 42 on the base substrate 1.

(9) as shown in FIG. 9, forming a pixel defining layer 11.

Specifically, a pattern of the pixel defining layer 11 may be exposed by coating and exposing one layer of a photosensitive material for the pixel defining layer on the base substrate 1 of the above (8).

When the pixel defining layer is formed, the pixel defining layer material will be filled into the bottom of the undercut step. During the exposure of the pixel defining layer material, the exposure light is reflected by the reflective pattern 42, the exposure of the pixel-defining layer material at the bottom of the undercut step structure is enhanced, and the pixel-defining layer material at the bottom of the undercut step structure is completely exposed and removed, thereby preventing the pixel-defining layer material from remaining at the bottom of the undercut step structure, and being capable of retaining the original undercut step structure. Thus, in the subsequent preparation of the cathode, the cathode will be broken at the edge of the upper surface of the undercut step structure during the deposition. In the preparation of the packaging layer, the packaging layer is capable of covering a side surface of the cathode, to block water and oxygen from penetrating into the OLED display substrate along the cathode and to ensure and to ensure the packaging effect of the OLED display substrate, thereby ensuring the performance of the display device, and being capable of preparing a profiled organic light-emitting display.

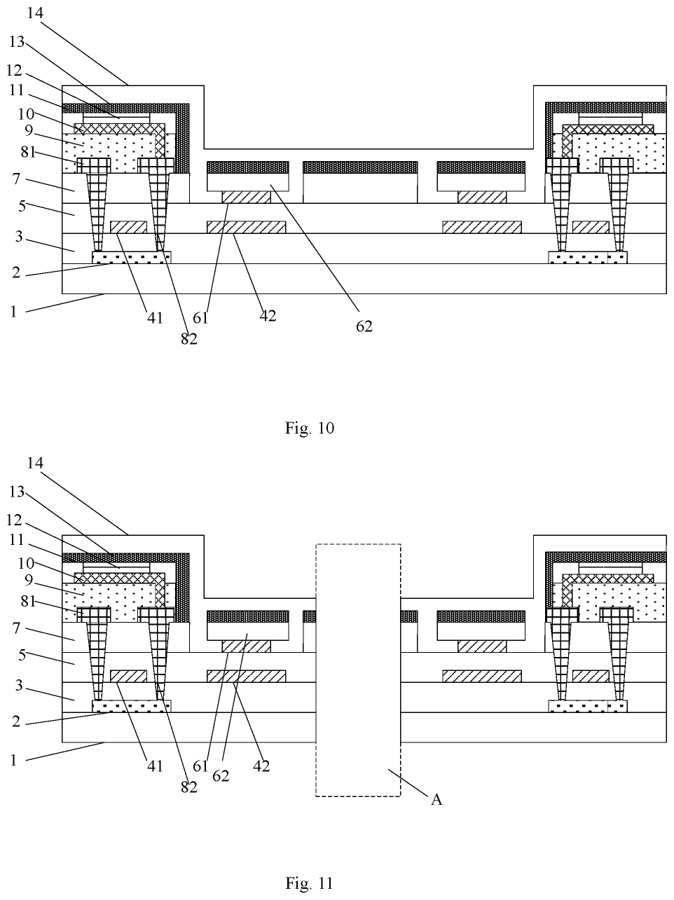

(10) as shown in FIG. 10, forming an organic light-emitting layer 12, a cathode 13 and an packaging layer 14.

Specifically, the organic light-emitting layer 12 can be formed by evaporation or inkjet printing.

When the cathode material is deposited to form the cathode 13, the cathode material can be broken at the edge of the upper surface of the undercut step structure.

As shown in FIG. 10, since the cathode material can be broken at the edge of the upper surface of the undercut step structure, the subsequently formed packaging layer 14 is capable of covering the side surface of the cathode 13, and the packaging layer 14 may include an inorganic film or an organic film and an inorganic film stacked.

(11) as shown in FIG. 11, the OLED display substrate is cut to remove the cutting region A.

Since the packaging layer 14 covers the side surface of the cathode 13, the side surface of the cathode 13 is not exposed after removing the cutting region A, to block water and oxygen from penetrating into the OLED display substrate along the cathode, and to ensure the packaging effect of the OLED display substrate, thereby ensuring the performance of the display device, and being capable of preparing a profiled organic light-emitting display, in which the shape of the cutting region A, which can be set as needed, can be rectangular, circular or the like.

The OLED display substrate of the present embodiment can be prepared by the operations of the above (1) to (11).

### Example 2

The method for preparing the OLED display substrate according to this Example includes the following operations.

(1) providing a base substrate, on which a reflective pattern is formed.

The base substrate 1 may be a rigid substrate or a flexible substrate, in which the rigid substrate includes a glass substrate and a quartz substrate, and the flexible substrate includes a PI (polyimide) substrate.

Specifically, a metal layer having a thickness of about 500 to 4,000 Å may be deposited on the base substrate by sputtering or thermal evaporation. The material of the metal layer may be selected from Cu, Al, Ag, Mo, Cr, Nd, Ni, Mn, Ti, Ta, W and other metals and alloys of these metals, and the metal layer may be a single layer structure or a multilayer structure, such as Cu\Mo, Ti\Al\Ti, and Mo\Al\Mo. A layer of photoresist is coated on the metal layer, and the photoresist is exposed by using a mask to form a photoresist unreserved region and a photoresist reserved region, in which the photoresist reserved region corresponds to a region in which the reflective pattern is located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the metal film of the photoresist unreserved region is completely etched by an etching process, and the remaining photoresist is stripped to form a reflective pattern.

(2) forming an active layer of the thin-film transistor.

Specifically, one layer of a semiconductor material is deposited on the base substrate, one layer of a photoresist is coated on the semiconductor material, and the photoresist is exposed by using a mask to form a photoresist unreserved region and a photoresist reserved region, in which the photoresist reserved region corresponds to a region in which the pattern of the active layer is located, and the photoresist unreserved region corresponds to a region outside of the pattern of the active layer. A development processing is performed, so that the photoresist in the photoresist unreserved region is completely removed, and the thickness of the photoresist in the photoresist reserved region remains unchanged; and the semiconductor material of the photoresist unreserved region is completely etched by an etching process to form a pattern of the active layer, and the remaining photoresist is stripped.

(3) forming a first gate insulating layer.

Specifically, a first gate insulating layer having a thickness of 500 to 5,000 Å may be deposited on base substrate of the above (2) by a plasma enhanced chemical vapor deposition (PECVD) method. The material of the first gate insulating layer may be selected from an oxide, a nitride. or an oxynitride, and the reaction gas is SiH₄, NH₃, N₂ or SiH₂Cl₂, NH₃, N₂.

(4) forming a gate electrode of the thin-film transistor, and then forming a second gate insulating layer.

Specifically, a gate metal layer having a thickness of about 500 to 4,000 Å may be deposited on the first gate insulating layer by sputtering or thermal evaporation. The material of the gate metal layer may be selected from Cu, Al, Ag, Mo, Cr, Nd, Ni, Mn, Ti, Ta, W and other metals and alloys of these metals, and the gate metal layer may be a single layer structure or a multilayer structure, such as Cu\Mo, Ti\Al\Ti, and Mo\Al\Mo. A layer of photoresist is coated on the gate metal layer, and the photoresist is exposed by using a mask to form a photoresist unreserved region and a photoresist reserved region, in which the photoresist reserved region corresponds to a region in which the gate electrode and other first gate metal layer pattern are located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the gate metal film of the photoresist unreserved region is completely etched by an etching process, and the remaining photoresist is stripped to form a gate electrode and other first gate metal layer pattern.

A second gate insulating layer having a thickness of 500 to 5,000 Å may be deposited by a plasma enhanced chemical vapor deposition (PECVD) method. The material of the second gate insulating layer may be selected from an oxide, a nitride. or an oxynitride, and the reaction gas is SiH₄, NH₃, N₂ or SiH₂Cl₂, NH₃, N₂.

(5) forming a transition pattern of the first pattern and an interlayer insulating layer.

Specifically, a gate metal layer having a thickness of about 500 to 4,000 Å may be deposited on the second gate insulating layer by sputtering or thermal evaporation. The material of the gate metal layer may be selected from Cu, Al, Ag, Mo, Cr, Nd, Ni, Mn, Ti, Ta, W and other metals and alloys of these metals, and the gate metal layer may be a single layer structure or a multilayer structure, such as Cu\Mo, Ti\Al\Ti, and Mo\Al\Mo. A layer of photoresist is coated on the gate metal layer, and the photoresist is exposed by using a mask to form a photoresist unreserved region and a photoresist reserved region, in which the photoresist reserved region corresponds to a region in which the transition pattern of the first pattern and other second metal layer pattern are located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the gate metal film of the photoresist unreserved region is completely etched by an etching process, and the remaining photoresist is stripped to form a transition pattern of the first pattern and other second gate metal layer pattern, in which the transition pattern of the first pattern surrounds the cutting region of the OLED display substrate.

An interlayer insulating layer having a thickness of 500 to 5,000 Å may be deposited by a plasma enhanced chemical vapor deposition (PECVD) method. The material of the interlayer insulating layer may be selected from an oxide, a nitride. or an oxynitride, and the reaction gas is SiH₄, NH₃, N₂ or SiH₂Cl₂, NH₃, N₂.

(6) etching the first gate insulating layer, the second gate insulating layer and the interlayer insulating layer to form a via hole exposing the active layer and a via hole exposing a side surface of the transition pattern of the first pattern.

(7) forming a source electrode and a drain electrode of the thin-film transistor.

Specifically, by magnetron sputtering, thermal evaporation or other film formation methods, a source/drain metal layer having a thickness of approximately 2000 to 4000 Å may be deposited on the base substrate of the above (6). The material of the source/drain metal layer may be selected from a metal such as Cu, Al, Ag, Mo, Cr, Nd, Ni, Mn, Ti, Ta, and W, and an alloy of these metals. The source/drain metal layer may be a single layer structure or a multilayer structure, such as Cu\Mo, Ti\Al\Ti, and Mo\Al\Mo. One layer of photoresist is coated on the source/drain metal layer, and the photoresist is exposed by using a mask to form a photoresist unreserved region and a photoresist reserved region, in which the photoresist reserved region corresponds to a region in which the patterns of the source electrode and the drain electrode are located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the source/drain metal layer of the photoresist unreserved region is completely etched by an etching process, and the remaining photoresist is stripped to form a source electrode and a drain electrode, in which the source electrode and the drain electrode are respectively connected to the active layer through via holes.

(8) forming an overcoat.

Specifically, a pattern of the overcoat can be formed by coating and exposing one layer of an organic resin on the base substrate of the above (7).

(9) forming an anode.

Specifically, ITO, Ag and ITO may be deposited in sequence on the base substrate of the above (8), a photoresist is coated on the uppermost ITO, and the photoresist is exposed by using a mask to form a photoresist unreserved region and a photoresist reserved region, in which the photoresist reserved region corresponds to a region in which the pattern of the anode electrode is located, and the photoresist unreserved region corresponds to a region outside of the above pattern. A development processing is performed, so that the photoresist in the photoresist unreserved region is completely removed, and the thickness of the photoresist in the photoresist reserved region remains unchanged; and the ITO of the photoresist unreserved region, Ag and ITO are completely etched by an etching process, and the remaining photoresist is stripped to form a pattern of the anode.

When ITO, Ag and ITO are etched, the etchant simultaneously etches the exposed side surface of the transition pattern, and the transition pattern is indented inward by 0.1 mm to 10 mm to form the first pattern. The first pattern and the remaining interlayer insulating layer portion thereon (i.e., the second pattern) constitute an undercut step structure, in which the undercut step structure surrounds the cutting region of the OLED display substrate, and the orthogonal projection of the first pattern on the base substrate falls within the orthogonal projection of the reflective pattern on the base substrate.

(10) forming a pixel defining layer.

Specifically, a pattern of the pixel defining layer may be exposed by coating and exposing one layer of a photosensitive material for the pixel defining layer on the base substrate of the above (9).

In the preparation of the pixel defining layer, the pixel defining layer material is filled into the bottom of the undercut step structure. During the exposure of the pixel defining layer material, the exposure light is reflected by the reflective pattern, the exposure of the pixel-defining layer material at the bottom of the undercut step structure is enhanced, and the pixel-defining layer material at the bottom of the undercut step structure is completely exposed and removed, thereby preventing the pixel-defining layer material from remaining at the bottom of the undercut step structure, and being capable of retaining the original undercut step structure. Thus, in the subsequent preparation of the cathode, the cathode will be broken at the edge of the upper surface of the undercut step structure during the deposition. In the preparation of the packaging layer, the packaging layer is capable of covering a side surface of the cathode, to block water and oxygen from penetrating into the OLED display substrate along the cathode and to ensure and to ensure the packaging effect of the OLED display substrate, thereby ensuring the performance of the display device, and being capable of preparing a profiled organic light-emitting display.

(11) forming an organic light-emitting layer, a cathode, and an packaging layer.

Specifically, the organic light-emitting layer can be formed by evaporation or inkjet printing.

When the cathode material is deposited to form the cathode, the cathode material can be broken at the edge of the upper surface of the undercut step structure.

Since the cathode material can be broken at the edge of the upper surface of the undercut step structure, the subsequently formed packaging layer is capable of covering the side surface of the cathode, and the packaging layer may include an inorganic film or an organic film and an inorganic film stacked.

(12) the OLED display substrate is cut to remove the cutting region.

Since the packaging layer covers the side surface of the cathode, the side surface of the cathode is not exposed after removing the cutting region, to block water and oxygen from penetrating into the OLED display substrate along the cathode, and to ensure the packaging effect of the OLED display substrate, thereby ensuring the performance of the display device, and being capable of preparing a profiled organic light-emitting display, in which the shape of the cutting region A, which can be set as needed, can be rectangular, circular or the like.

The OLED display substrate of the present embodiment can be prepared by the operations of the above (1) to (12).

An embodiment of the present disclosure further provides a display device including the OLED display substrate as described above. The display device may be any product or component having a display function, such as a television, a display, a digital photo frame, a mobile phone, a tablet computer, etc., in which the display device further includes a flexible circuit board, a printed circuit board, and a backplane.

In this embodiment, a reflective pattern is formed between the inverted frustum structure and the base substrate. In the preparation of the pixel defining layer, the pixel defining layer material is filled into the bottom of the inverted frustum structure. During the exposure of the pixel defining layer material, the exposure light is reflected by the reflective pattern, the exposure of the pixel-defining layer material at the bottom of the inverted frustum structure is enhanced, and the pixel-defining layer material at the bottom of the inverted frustum structure is completely exposed and removed, thereby preventing the pixel-defining layer material from remaining at the bottom of the inverted frustum structure, and being capable of retaining the original inverted frustum structure. Thus, in the subsequent preparation of the cathode, the cathode will be broken at the edge of the upper surface of the inverted frustum structure during the deposition. In the preparation of the packaging layer, the packaging layer is capable of covering a side surface of the cathode, to block water and oxygen from penetrating into the OLED display substrate along the cathode and to ensure and to ensure the packaging effect of the OLED display substrate, thereby ensuring the performance of the display device, and being capable of preparing a profiled organic light-emitting display.

In the method embodiments of the present disclosure, the serial numbers of the operations cannot be used to define the sequence of the operations. As for one skilled in the art, the changes in the order of operations without paying creative work also fall within the scope of the present disclosure.

Unless otherwise defined, technical terms or scientific terms used herein have the normal meaning commonly understood by one skilled in the art in the field of the present disclosure. The words “first”, “second”, and the like used in the present disclosure does not denote any order, quantity, or importance, but rather merely serves to distinguish different components. The “including”, “comprising”, and the like used in the present disclosure means that the element or item appeared in front of the word encompasses the element or item and their equivalents listed after the word, and does exclude other elements or items. The word “connected” or “connecting” and the like are not limited to physical or mechanical connections, but may include electrical connections, whether direct or indirect. “On”, “under”, “left”, “right” and the like are only used to represent relative positional relationships, and when the absolute position of the described object is changed, the relative positional relationship may also be changed, accordingly.

It will be understood that when an element, such as a layer, film, region, or substrate, is referred to as being “on” or “under” another element, the element may be directly “on” or “under” another element, or there may be an intermediate element.

The above descriptions are preferred embodiments of the present disclosure. It should be noted that one skilled in the art would make several improvements and substitutions without departing from the principles of the present disclosure. These improvements and modifications should also be regarded as the protection scope of the present disclosure.

What is claimed is:

1. A method for preparing an Organic Light-Emitting Diode (OLED) display substrate, comprising:
forming an inverted frustum structure surrounding an cutting region of the OLED display substrate, with an area of an end surface of the inverted frustum structure away from a base substrate of the OLED display substrate being greater than an area of an end surface proximate to the base substrate, such that when forming a cathode of the OLED display substrate, the cathode is broken spontaneously at an edge of an upper surface of the inverted frustum structure; and
forming a reflective pattern between the inverted frustum structure and the base substrate before forming the inverted frustum structure, such that an orthogonal projection of the inverted frustum structure on the base substrate is located within an orthogonal projection of the reflective pattern on the base substrate.

2. The method for preparing the OLED display substrate of claim 1, wherein the forming the reflective pattern comprises:
forming the reflective pattern and a first metal layer pattern of the OLED display substrate by a single patterning process.

3. The method for preparing the OLED display substrate of claim 1, wherein the forming the inverted frustum structure comprises:
forming a first pattern and a second pattern which are stacked, with the first pattern being located between the second pattern and the base substrate, and with an orthogonal projection of the first pattern on the base substrate being located within an orthogonal projection of the second pattern on the base substrate.

4. The method for preparing the OLED display substrate of claim 3, wherein the forming the first pattern comprises:
forming a transition pattern of the first pattern; and
etching a side surface of the transition pattern of the first pattern with the second pattern as a mask after forming the second pattern, such that the transition pattern of the first pattern is indented inward to form the first pattern.

5. The method for preparing the OLED display substrate of claim 4, wherein the forming the transition pattern of the first pattern comprises:
forming the transition pattern of the first pattern and a second metal layer pattern of the OLED display substrate by a single patterning process.

6. The method for preparing the OLED display substrate of claim 5, wherein the forming the reflective pattern comprises:
forming the reflective pattern and a first metal layer pattern of the OLED display substrate by a single patterning process, with the first metal layer pattern being a first gate metal layer pattern, and with the second metal layer pattern being a second gate metal layer pattern.

7. The method for preparing the OLED display substrate of claim 5, wherein the forming the reflective pattern comprises: forming the reflective pattern and a first metal layer pattern of the OLED display substrate by a single patterning process, with the first metal layer pattern being a second gate metal layer pattern, and with the second metal layer pattern being a source/drain metal layer pattern.

8. The method for preparing the OLED display substrate of claim 7, wherein the second pattern is formed by using a passivation layer on the source/drain metal layer.

9. The method for preparing the OLED display substrate of claim 5, wherein the forming the reflective pattern comprises:
forming the reflective pattern and a first metal layer pattern of the OLED display substrate by a single patterning process, with the first metal layer pattern being located in a same layer as the reflective pattern and formed of a same material as the reflective pattern, and with the second metal layer pattern being located in a same layer as the first pattern and formed of a same material as the first pattern.

10. An OLED display substrate, comprising:
a base substrate;
an inverted frustum structure surrounding an cutting region, with an area of an end surface of the inverted frustum structure away from a base substrate of the OLED display substrate being greater than an area of an end surface proximate to the base substrate;
a cathode broken spontaneously at an edge of an upper surface of the inverted frustum structure; and
a reflective pattern located between the inverted frustum structure and the base substrate,
wherein an orthogonal projection of the inverted frustum structure on the base substrate is located within an orthogonal projection of the reflective pattern on the base substrate.

11. The OLED display substrate of claim 10, further comprising a first metal layer pattern located in a same layer as the reflective pattern and formed of a same material as the reflective pattern.

12. The OLED display substrate of claim 10, wherein the inverted frustum structure comprises a first pattern and a second pattern, with the first pattern being located between the second pattern and the base substrate, and with an orthogonal projection of the first pattern on the base substrate being located within an orthogonal projection of the second pattern on the base substrate.

13. The OLED display substrate of claim 12, further comprising a second metal layer pattern located in a same layer as the first pattern and formed of a same material as the first pattern.

14. The OLED display substrate of claim 10, further comprising a first metal layer pattern and a second metal layer pattern, with the first metal layer pattern being a first gate metal layer pattern, and with the second metal layer pattern being a second gate metal layer pattern.

15. The OLED display substrate of claim 10, further comprising a first metal layer pattern and a second metal layer pattern, with the first metal layer pattern being a second gate metal layer pattern, and with the second metal layer pattern being a source/drain metal layer pattern.

16. The OLED display substrate of claim 15, wherein the second pattern is formed by using a passivation layer on the source/drain metal layer.

17. A display device, comprising the OLED display substrate of claim 10.

18. A display device of claim 17, wherein the OLED display substrate further comprises a first metal layer pattern located in a same layer as the reflective pattern and formed of a same material as the reflective pattern.

19. The display device of claim 17, wherein the inverted frustum structure comprises a first pattern and a second pattern, with the first pattern being located between the second pattern and the base substrate, and with an orthogonal projection of the first pattern on the base substrate being located within an orthogonal projection of the second pattern on the base substrate.

20. A display device of claim 19, wherein the OLED display substrate further comprises a second metal layer pattern located in a same layer as the first pattern and formed of a same material as the first pattern.
